(19) United States
(12) Patent Application Publication
(10) Pub. No.: US 2021/0091268 A1
(43) Pub. Date: Mar. 25, 2021

(54) COLOR TUNABLE LIGHT EMISSION DIODE AND MICRO LED DISPLAY

(71) Applicants: Lehigh University, Bethlehem, PA (US); Osaka University, Osaka (JP)

(72) Inventors: Volkmar Dierolf, Allentown, PA (US); Brandon Mitchell, Kennett Square, PA (US); Ruoqiao Wei, Bethlehem, PA (US); Yasufumi Fujiwara, Osaka (JP); Tomasz Gregorkiewicz, Osaka (JP); Shuhei Ichikawa, Osaka (JP); Jun Tatebayashi, Osaka (JP); Dolf Timmerman, Osaka (JP)

(21) Appl. No.: 16/848,175

(22) Filed: Apr. 14, 2020

Related U.S. Application Data
(60) Provisional application No. 62/904,173, filed on Sep. 23, 2019.

(51) Int. Cl. H01L 33/32; H01L 33/06; H01L 33/12; H01L 33/50; H01L 25/075; H01L 33/08

(52) U.S. Cl. CPC H01L 33/325; H01L 33/06; H01L 33/08; H01L 33/502; H01L 25/0753; H01L 33/12

(57) ABSTRACT

A color tunable light emission diode in which the color tone of the emission color changes by controlling the injection current, which has an active layer sandwiched between a p-type layer and an n-type layer on a substrate, and the active color layer is formed by doping Eu and Mg to an AlGaInN-based material which is GaN, InN, AlN or a mixed crystal of any two or more of them; and a micro LED display, wherein its display unit is formed by integrating image pixels having the above color tunable light emission diode are provided; and a light emitting semiconductor device technology capable of providing an ultra-small and high definition micro LED display can be provided.

### CROSS-REFERENCE TO RELATED APPLICATIONS

The present application claims the benefit of priority to U.S. Provisional Application No. 62/904,173 filed Sep. 23, 2019, which is incorporated herein by reference in its entirety.

### TECHNICAL FIELD

The present invention relates to a color tunable light emission diode and a micro LED display. More particularly, the present invention relates to a color tunable light emission diode in which the color tone of the emission color changes by controlling the injection current, and to a micro LED display provided with the above color tunable light emission diode as an image pixel and capable of drawing ultra-small and high-definition images.

### BACKGROUND

In a conventional micro LED display, a blue LED chip and a green LED chip made of an InGaN/GaN-based material and a red LED chip (hereinafter, “LED chip” may simply be referred to “LED”) made of an AlGaInP/GaAs-based material are physically arranged on one substrate to constitute an image pixel, and the light emission intensity from each chip is adjusted by controlling the injection current to each chip so that various colors can be expressed for each pixel.

In recent years, the development of mobile devices, such as smartphones and tablet terminals, has been remarkable, and accordingly, there has been an increasing social demand for micro LED displays capable of drawing ultra-small and high-definition images (ultra-small/high-definition micro LED displays).

The key technology for realizing ultra-small/high-definition micro LED displays is “How to integrate blue, green and red LEDs with small chip size on the same substrate”. However, in the conventional micro LED display, although a blue LED and a green LED can be integrated on the same substrate, since they are nitride semiconductors, a red LED cannot be integrated together with the blue LED and the green LED on the same substrate, since the red LED is not a nitride semiconductor.

Therefore, it has been desired to realize a red LED using a nitride semiconductor so that the red LED can be integrated with the blue LED and the green LED on the same substrate.

Under these circumstances, there has been invented a red LED of narrow-band and ultra-stable wave-length using GaN to which europium (Eu), one of the rare earth elements, is doped, ahead of the world, and have developed a technology that leads to integration of blue, green and red LEDs on the same substrate.

However, as long as the integration method of blue, green and red LEDs on the same substrate is such that the three LED chips are physically arranged on the same substrate to constitute one image pixel, there are limits to ultra-miniaturization and high definition of the micro LED display.

That is, each LED chip has a size of at least 20 μm square and the pixel size becomes an integral multiple of the chip size, when these are physically arranged on the same substrate. Therefore, there is a limit to the ultra-miniaturization of the pixel and it has been difficult to make a micro LED display ultra-small and high-definition sufficiently.

### BRIEF SUMMARY

In view of the above, an object of the present invention is to provide a light emitting semiconductor device technology capable of providing an ultra-small and high definition micro LED display by constituting an image pixel with one LED chip capable of emitting blue, green and red light to enable a variety of color expressions, thereby achieving ultra-small pixels.

The present inventors have conducted intensive studies and found that the above-described problems can be solved by the invention described below, and have completed the present invention.

According to the present invention, one image pixel is constituted by one LED chip capable of emitting blue, green and red lights, and variety of colors can be expressed. As a result, the image pixels can be ultra-miniaturized, and a light emitting semiconductor device technology capable of providing an ultra-small and high definition micro LED display can be provided.

The invention according to claim 1 is: a color tunable light emission diode in which the color tone of the emission color changes by controlling the injection current, which has an active layer sandwiched between a p-type layer and an n-type layer on a substrate, and the active layer is formed by doping Eu and Mg to an AlGaInN-based material which is GaN, InN, AlN or a mixed crystal of any two or more of them.

The invention according to claim 2 is the color tunable light emission diode according to claim 1, wherein the active layer has a quantum well structure in which barrier layers made of AlGaInN-based material and well layers made of AlGaInN-based material are alternately stacked, wherein the AlGaInN-based material of the barrier layer is a material represented by AlxGayIn1-x-yN, and the AlGaInN-based material of the well layer is a material represented by Alx′Gay′In1-x′-y′N, x, x′, y and y′ are set so that the electron affinity κ(barrier) and band gap εg(barrier) of the AlxGayIn1-x-yN, and the electron affinity κ(well) and band gap εg(well) of the Alx′Gay′In1-x′-y′N satisfy the following formulas:

κ(barrier)<κ(well)

κ(barrier)+εg(barrier)>κ(well)+εg(well)

In the above, x and x′ are numbers from 0 to 1, y and y′ are numbers from 0 to 1, and x+y and x′+y′ are numbers from 0 to 1.

The invention according to claim 3 is the color tunable light emission diode according to claim 1 or claim 2, wherein the barrier layer is an AlGaN layer, and the well layer is a GaN layer.

The invention according to claim 4 is the color tunable light emission diode according to any one of claims 1 to 3, wherein the amount of Eu doped to each of the well layers is 1×1017 to 5×1021 cm−3.

The invention according to claim 5 is the color tunable light emission diode according to any one of claims 1 to 4, wherein the amount of Mg doped to each of the well layers is 1×1018 to 1×1020 cm−3.

The invention according to claim 6 is the color tunable light emission diode according to any one of claims 1 to 5, wherein Si is further doped to each of the well layers.

The invention according to claim 7 is the color tunable light emission diode according to claim 6, wherein the amount of Si doped to each of the well layers is 1×1017 to 5×1021 cm−3.

The invention according to claim 8 is the color tunable light emission diode according to any one of claims 1 to 7, wherein the thickness of the barrier layer is 0.5 to 50 nm per layer, and the thickness of the well layer is 0.1 to 20 nm per layer.

The invention according to claim 9 is the color tunable light emission diode according to any one of claims 1 to 8, wherein an ud-GaN layer is formed as a buffer layer between the barrier layer and the well layer.

The invention according to claim 10 is the color tunable light emission diode according to any one of claims 1 to 9, wherein the thickness of the buffer layer is 0.1 to 20 nm per layer.

The invention according to claim 11 is a micro LED display, wherein its display unit is formed by integrating image pixels having the color tunable light emission diode according to any one of claims 1 to 10.

The invention according to claim 12 is a micro LED display, wherein its display unit is formed by integrating image pixels each of which is formed by arranging a light emission diode in which Eu is doped to an AlGaInN-based material that is GaN, InN, AlN or a mixed crystal of any two or more of them and a light emission diode in which Mg is doped to an AlGaInN-based material that is GaN, InN, AlN or a mixed crystal of any two or more of them, on the same pixel substrate.

Further areas of applicability of the present invention will become apparent from the detailed description provided hereinafter. It should be understood that the detailed description and specific examples, while indicating the preferred embodiment of the invention, are intended for purposes of illustration only and are not intended to limit the scope of the invention.

### BRIEF DESCRIPTION OF THE DRAWINGS

The present invention will become more fully understood from the detailed description and the accompanying drawings, wherein like elements are labeled similarly and in which:

FIG. 1 A diagram illustrating the mechanism of red light emission and green light emission in the present invention.

FIG. 2 A diagram illustrating a change in emission color accompanying injection of a pulse current in a color tunable light emission diode according to one embodiment of the present invention.

FIG. 3 A diagram for explaining light emission in a GaN:Eu layer to which Mg is doped as an impurity in a color tunable light emission diode according to one embodiment of the present invention.

FIG. 4 A chromaticity diagram (CIE chromaticity diagram) for explaining a range of colors that can be emitted by a color tunable light emission diode according to one embodiment of the present invention.

FIG. 5 A schematic view showing an example of a configuration of a color tunable light emission diode according to an example of an embodiment of the present invention.

FIG. 6 A diagram showing energy levels in the quantum well structure of the present embodiment.

### DETAILED DESCRIPTION

The features and benefits of the invention are illustrated and described herein by reference to exemplary embodiments. This description of exemplary embodiments is intended to be read in connection with the accompanying drawings, which are to be considered part of the entire written description. Accordingly, the disclosure expressly should not be limited to such exemplary embodiments illustrating some possible non-limiting combination of features that may exist alone or in other combinations of features.

In the description of embodiments disclosed herein, any reference to direction or orientation is merely intended for convenience of description and is not intended in any way to limit the scope of the present invention. Relative terms such as “lower,” “upper,” “horizontal,” “vertical,”, “above,” “below,” “up,” “down,” “top” and “bottom” as well as derivatives thereof (e.g., “horizontally,” “downwardly,” “upwardly,” etc.) should be construed to refer to the orientation as then described or as shown in the drawing under discussion. These relative terms are for convenience of description only and do not require that the apparatus be constructed or operated in a particular orientation. Terms such as “attached,” “affixed,” “connected,” “coupled,” “interconnected,” and similar refer to a relationship wherein structures are secured or attached to one another either directly or indirectly through intervening structures, as well as both movable or rigid attachments or relationships, unless expressly described otherwise.

As used throughout, any ranges disclosed herein are used as shorthand for describing each and every value that is within the range. Any value within the range can be selected as the terminus of the range. In addition, all references cited herein are hereby incorporated by reference in their entireties. In the event of a conflict in a definition in the present disclosure and that of a cited reference, the present disclosure controls.

### [1] Basic Concept of the Present Invention

Before describing specific embodiments of the present invention, the basic concept of the present invention will be described.

As described above, the present inventors have invented a red LED (GaN:Eu LED) of narrow band and ultra-stable wave-length using Eu-doped GaN ahead of the world, and have developed a technology that leads to integration of blue, green and red LEDs on the same substrate.

However, after further study, it was found that the GaN:Eu LED can surprisingly emit not only red light but also green light when the current injection condition is changed.

Specifically, in the case of GaN:Eu LED, the Eu³⁺ ion emits red light due to the transition from ⁵D0 to ⁷F2 in the 4f shell (⁵D0→⁷F2 transition in the 4f shell). Since the emission lifetime is relatively long at 200 to 300 μs, if a current is injected in a pulsed manner at intervals shorter than the emission lifetime, Eu³⁺ ions are further excited to a level (⁵D1) having an energy higher than the ⁵D0 level. It was found that a 4f intra-shell transition from ⁵D1 to ⁷F2 occurred newly, resulting in green light emission. Then, it was found that by controlling the injection current, red light emission and green light emission were appropriately mixed, and various color expressions from red to orange and from orange to green were possible.

After further study, it was found that, when Mg was doped as an impurity to Eu-doped GaN, blue light emission involving Mg was observed in addition to red light emission by Eu³⁺ ions, and the emission intensities of red emission and blue emission changed by controlling the injection current. In the case of such mixed luminescence of red and blue, blue luminescence can be taken out alone by applying a filter. Therefore, by adding the blue luminescence to the red luminescence and green luminescence of the Eu-doped GaN described above, three primary colors of light can be secured.

As described above, the GaN:Eu LED to which Mg is doped as an impurity can emit light of each of the three primary colors of red, green and blue. Therefore, by mixing the luminescent colors appropriately by controlling the current injection conditions appropriately, it is possible to freely express colors.

Based on this knowledge, it becomes possible to make an image pixel with one LED chip (GaN:Eu LED chip with Mg doped as an impurity). As a result, size of the element itself can be miniaturized as small as possible, the pixel size can be sufficiently reduced to one third of the conventional size, and high definition of screen can be achieved.

Such knowledge is the first discovery in the world, and will greatly pave the way for providing ultra-small and high-definition micro LED displays.

### [2] Emission Mechanism in the Present Invention

Next, the mechanism of light emission in the color tunable light emission diode according to the present invention will be described.

(1) Red Light Emission and Green Light Emission

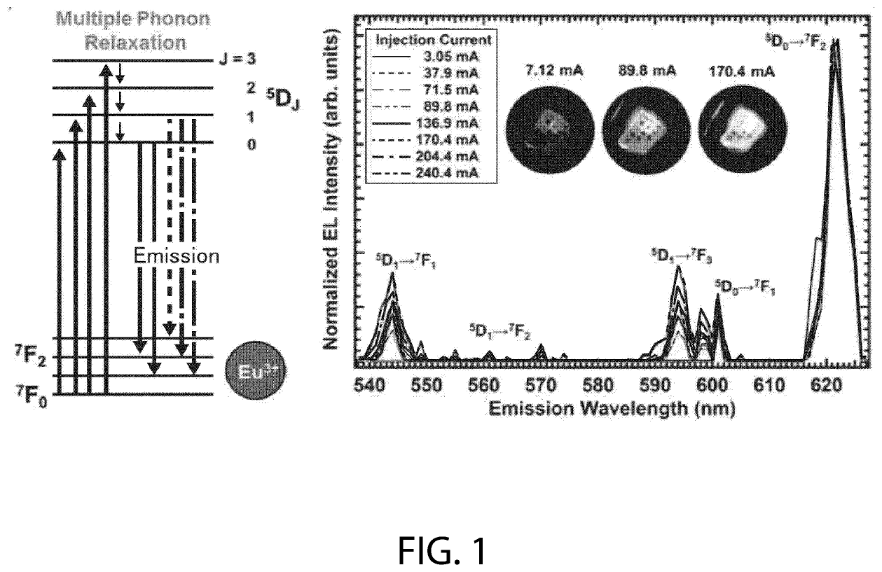

FIG. 1 is a diagram illustrating the mechanism of red light emission and green light emission in the present invention. In FIG. 1, the left diagram is a diagram for explaining the energy level and the transition scheme of the Eu³⁺ ion. The right diagram is a diagram for showing the relationship between the emission spectrum intensity and the wavelength according to the change in the injection current.

In the case of a low injection current of 10 mA or less, Eu³⁺ ions are first excited from the ⁷F0 level to the ⁵Dj level (j=0 to 3) as indicated by the upward solid line in the left diagram of FIG. 1. Then, it transitions from the ⁵D0 level (the Eu³⁺ ions excited to the ⁵D3 level, ⁵D2 level and ⁵D1 level also transition to the ⁵D0 level without emitting light) to the ⁷F1 level or the ⁷F2 level as shown by the downward solid line, and, at that time, red light having a wavelength of about 622 nm is emitted as shown in the right diagram of FIG. 1.

However, when the injection current is increased, the transition from the ⁵D1 level to the ⁷F3 level indicated by the downward dotted line and the transition from the ⁵D1 level to the ⁷F1 level or ⁷F2 level indicated by the downward dashed dotted line in the left diagram of FIG. 1 occur, without occurring a transition from the ⁵D1 level to the ⁵D0 level, and yellow-orange, green and green-yellow light are emitted, respectively. That is, as shown in the right diagram of FIG. 1, green light emission centering on a wavelength of about 545 nm is generated and its intensity increases as the injection current increases, while, on the other hand, the intensity of the light emission of the generated red light having a wavelength of about 622 nm is saturated at a certain magnitude. As a result, the green light emission and the red light emission are mixed, and the light-emission color is continuously changed to green, green-yellow, yellow-orange according to the change of the injection current.

Such a change in the light-emission color according to the injection current is caused by confining the Eu³⁺ ions excited to the ⁵D1 level and preventing the transition from the ⁵D1 level to the ⁵D0 level (carrier confinement).

Therefore, in the present invention, during the generation of the transition from the ⁵D0 level, that is, within the emission lifetime of red emission (200 to 300 μs), a rectangular pulse current is injected at a short interval and Eu³⁺ ions is re-excited to the ⁵D1 level to obtain a change in the emission color, as described above.

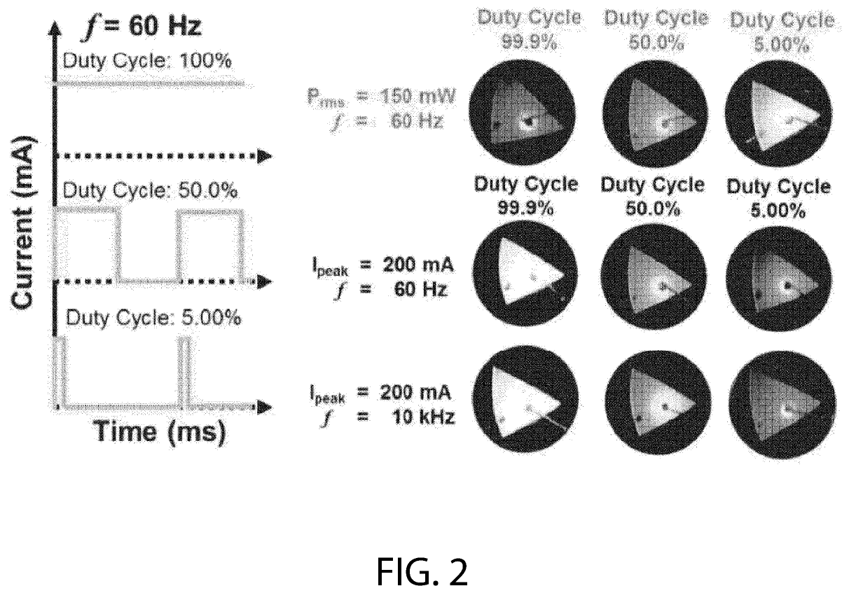

FIG. 2 is a diagram illustrating a change in emission color accompanying injection of a pulse current in a color tunable light emission diode according to one embodiment of the present invention. In FIG. 2, the left diagram is a diagram showing the “ON” time (duty cycle) under the condition of a frequency of 60 Hz. The right diagram shows the change of the emission color accompanying the change of the injection current. The upper part are diagrams showing how the change in the emission color occurs when the duty cycle changes under the conditions of a predetermined root mean square power Prms (150 mw) and a frequency f (60 Hz). The lower two parts are diagrams showing how the change in the emission color occurs when the frequency and duty cycle change under the condition of a predetermined peak current (200 mA).

In the upper part of the right diagram of FIG. 2, the emission color changes from red to yellow as the duty cycle decreases in the case of Prms 150 mw and f 60 Hz, and it can be seen that the emission color changes due to the change in the injection current. In the lower two parts on the right diagram of FIG. 2, when the peak current is fixed at 200 mA, the emission color changes from yellow to red as the duty cycle decreases, regardless of the frequency change. It can be seen that the emission color changes with the change in the injection current.

From these results, it was confirmed that the emission color of the GaN:Eu LED chip can be changed by changing the injection current.

(2) Blue Light Emission

It has been known that the GaN layer to which Mg is doped exhibits a blue color. However, what emission color is exhibited when Mg is doped as an impurity to the GaN:Eu layer has not been studied so far. As a result of experiments and studies, it was found that, in the case of a GaN:Eu layer to which Mg was doped as an impurity, blue light emission involving Mg could be observed in addition to red light emission by Eu³⁺ ions.

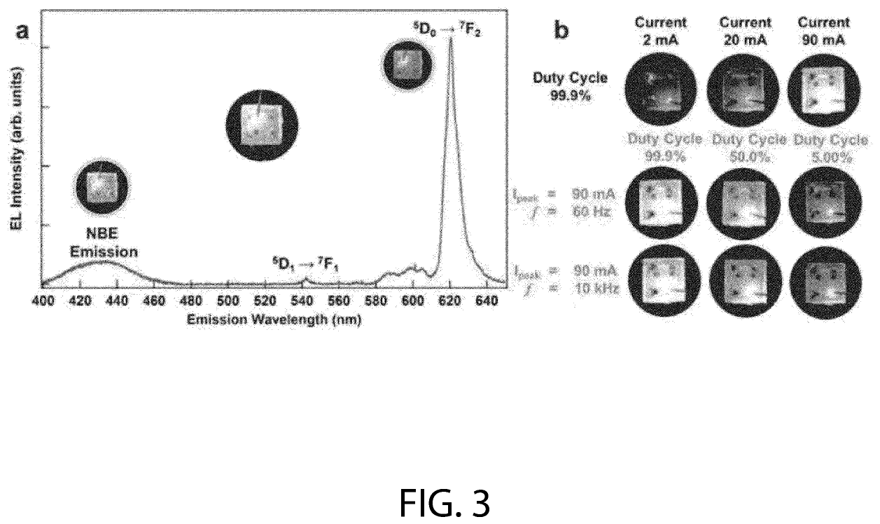

FIG. 3 is a diagram for explaining light emission in a GaN:Eu layer to which Mg is doped as an impurity in a color tunable light emission diode according to one embodiment of the present invention. In FIG. 3, the left diagram “a” is a diagram showing the relationship between the EL emission spectrum and the wavelength when a current of about 75 mA is injected into the Mg-doped GaN:Eu layer. And the right diagram “b” shows the change of the emission color with the change of the injection current. The upper part is a diagram showing how the change of the injection current results in a change in the emission color under the condition of the fixed duty cycle (99.9%). And the lower two parts are diagrams showing how changes in frequency and duty cycle under a predetermined peak current (90 mA) results in a change in emission color.

As shown in FIG. 3a, in the Mg-doped GaN:Eu layer, in addition to the red light emission at about 620 nm accompanying the transition of the Eu³⁺ ion from the ⁵D0 level to the ⁷F2 level, blue light emission due to Mg appears at about 420 nm, which is the GaN near band edge (NBE: near-band-edge), and, as shown in the center photograph, it can be seen as purple light emission in which red light and blue light are mixed. The photograph on the left shows blue light emission obtained using a 600 nm short-pass filter on this light emission, while the photograph on the right shows red light emission obtained using a 600 nm long-pass filter on this light emission. It can be seen that red light emission and blue light emission can be taken out independently by using a filter.

Mg doped as an impurity forms a shallower level than the native defects of GaN in the vicinity of the valence band, and this blue light emission is obtained by recombination of the injected carriers with a narrower energy width than the band gap(εg(well)) in the GaN:Eu layer (defect control: defect engineering).

In the upper part of FIG. 3b, the emission color changes from red to purple and purple to pink with increase in the injection current, and it can be seen that the emission color changes according to the change in the injection current. Also, in the lower two parts of FIG. 3b, when the peak current is fixed at 90 mA, regardless of the magnitude of the frequency, the color changes from pink to purple and purple to red accompanying decrease in the duty cycle, and it can be seen that the emission color changes with the change in the injection current.

If the amount of Mg is too small, sufficient blue light emission cannot be obtained, while if the amount of Mg is too large, blue light emission saturates. Considering this, the doped amount of Mg is preferably 1×1018 to 1×1020 cm−3. And it was found that, when Si was doped in addition to Mg, the emission intensity of blue light emission became higher. In this case, the specific amount of Si to be doped is preferably 1×1018 to 1×1020 cm−3.

(3) Chromaticity

Next, the luminescent colors that can be expressed by the above-described red, green and blue light emissions will be described.

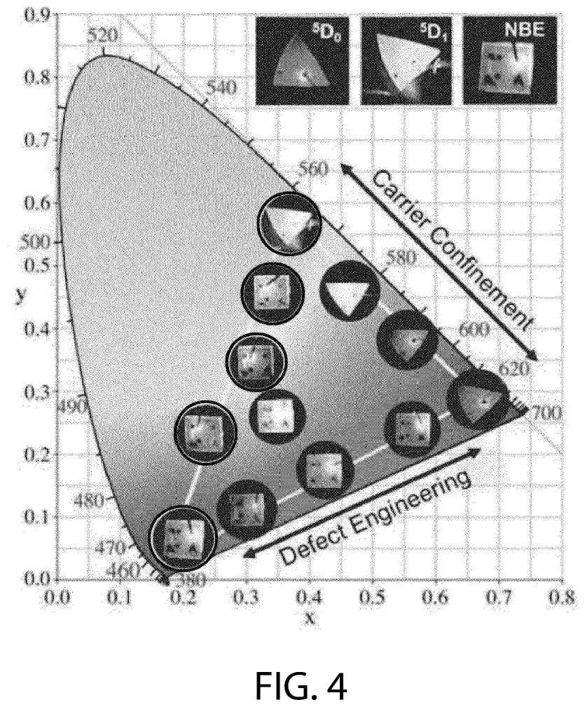

FIG. 4 is a chromaticity diagram (CIE chromaticity diagram) for explaining the range of colors that can be emitted by the color tunable light emission diode according to the present embodiment. A triangle having vertices each corresponding to three light emitting states of red light emission (⁵D0 state of Eu³⁺ ions), green light emission (⁵D1 state of Eu³⁺ ions), and blue light emission (separated light emission from the NBE level of GaN) is formed.

The emission from the NBE level of GaN is separated into blue or red using a 600 nm short-pass filter and a 600 nm long-pass filter (in FIG. 4, a solid circle surrounding each photograph indicates the use of the filter). In the upper part of FIG. 4, the light emission state at each vertex, that is, red light emission due to ⁵D0 transition of Eu³⁺ ion, green light emission due to ⁵D1 transition of Eu³⁺ ion, and blue light emission due to doped Mg at NBE are shown in order from the left.

It can be seen from FIG. 4 that the emission color gamut of the LED can be greatly expanded by appropriately combining the change from red to green due to the carrier confinement shown on the right side, the change from red to blue due to the combination with intentional defect engineering shown on the lower side, and the change from blue to green using the blue light separated by the filter.

That is, the colors in the triangle created by connecting these three points on the CIE chromaticity diagram can be appropriately emitted by mixing the emissions from these red, green, and blue levels additively. Therefore, the present embodiment enables light emission of various color expressions.

Specifically, since the lifespans of these three light emitting states are several orders of magnitude apart, it is possible to inhibit the light emission from one state and enhancing the light emission from another state with a shorter lifetime by increasing the injection current density, for example, by changing the time scale of the current flowing through the duty cycle during the pulse current injection. Thus, the color tone can be freely adjusted.

The technique of continuously changing the color tone of the emission color by simultaneously performing the above-described “carrier confinement” and “defect engineering” was first shown by the present inventors. The technique is epoch-making since one Eu doped GaN LED can be used as a three-color tunable light emission diode and it shows the possibility of miniaturizing the size of the device itself to the utmost.

### [3] Specific Embodiment

Next, the present invention will be described in more detail with reference to specific embodiments. The present invention is not limited to the embodiments described below, and various changes can be made within the same and equivalent scope as the present invention.

1. Color Tunable Light Emission Diode

(1) Overall Configuration

The color tunable light emission diode according to the present embodiment has an active layer sandwiched between a p-type layer and an n-type layer on a substrate, and the active layer is formed by doping Eu and Mg to an AlGaInN-based material which is GaN, InN, AlN or a mixed crystal of any two or more of them.

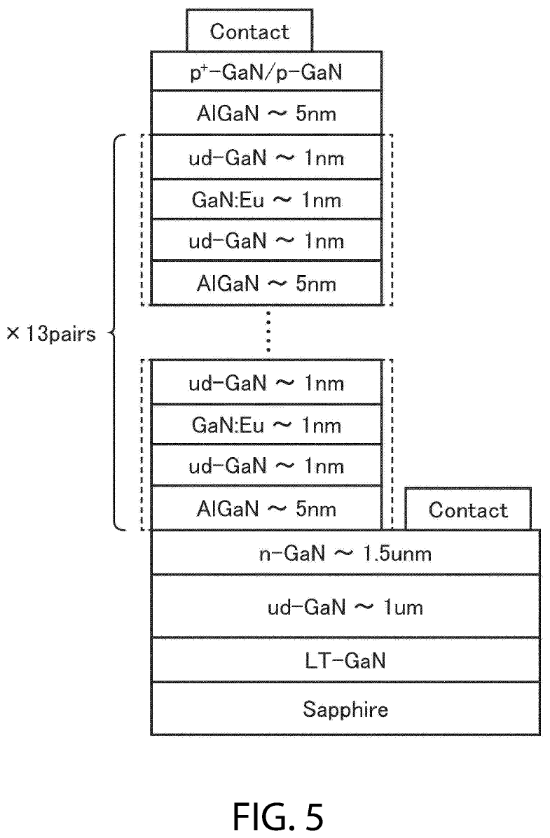

FIG. 5 is a schematic diagram showing an example of the configuration of the color tunable light emission diode according to the present embodiment. In the present embodiment, as the substrate, for example, a template is used which is a sapphire substrate on which an LT-GaN layer for preventing generation of cracks due to a difference in lattice constant between sapphire and GaN and an ud-GaN layer for suppressing the influence of dislocation due to sapphire substrate, and the like are formed as shown in FIG. 5. Note that SiC, Si, GaN, or the like may be used instead of the sapphire substrate.

Then, a GaN:Eu layer (Mg addition) serving as an active layer is formed on the Substrate. At this time, in order to obtain a higher emission intensity, it is preferable that an AlGaN layer serving as a barrier layer and a GaN:Eu layer serving as a well layer are alternately stacked (13 pairs in FIG. 5) to constitute a quantum well structure, as shown in FIG. 5. By providing such a quantum well structure, the carrier density can be increased by doping Eu³⁺ ions into the well layer, so that higher emission intensity can be obtained. Further, Mg doped as an impurity also transitions in the well layer, so that blue light with higher emission intensity can be emitted.

In the present embodiment, if the barrier layer is too thin, Eu³⁺ ions doped into the well layer escape and the carrier density around Eu cannot be increased. On the other hand, if the barrier layer is too thick, the effect saturates. Therefore, the thickness is preferably between 0.5 and 50 nm per layer.

If the well layer is too thin, Eu³⁺ ions cannot be sufficiently doped and the carrier density cannot be increased. On the other hand, if the well layer is too thick, the effect saturates. Therefore, the thickness is preferably between 0.1 and 20 nm per layer.

In the present embodiment, it is preferred that an ud-GaN layer is provided as a buffer layer between the barrier layer and the well layer for preventing Eu³⁺ ions from diffusing into the barrier layer, as shown in FIG. 5. Thus, Eu³⁺ ions can be sufficiently doped. The thickness of the buffer layer is preferably from 0.1 to 20 nm per layer.

In the present embodiment, the doping amount of Eu in the well layer is preferably 1×1017 to 5×1021 cm−3, considering that the amount of Eu³⁺ ions is insufficient when the amount is too small, and the red light emission saturates when the amount is too large.

(2) Quantum Well Structure

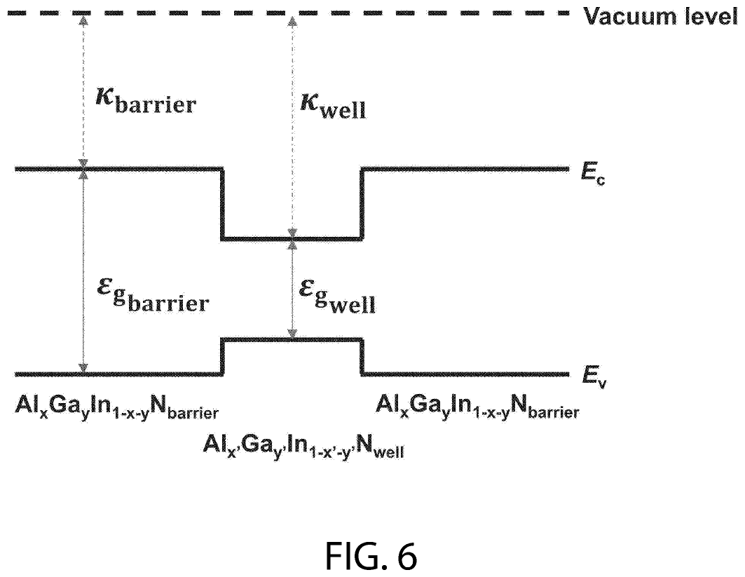

Next, the above quantum well structure will be described in detail. FIG. 6 is a diagram showing energy levels in the quantum well structure of the present embodiment. In FIG. 6, AlxGayIn1-x-yN is a barrier layer (barrier), Alx′Gay′In1-x′-y′N is a well layer (well), Ec indicates the conduction band bottom, Ev indicates the valence electron band top, κ indicates the electron affinity, and cg indicates the band gap. Vacuum level indicates the level of vacuum.

In the present embodiment, AlGaInN-based materials in which x, x′, y, and y′ are set so as to satisfy the following two formulas are used for the barrier layer and the well layer.

κ(barrier)<κ(well)

κ(barrier)+εg(barrier)>κ(well)+εg(well)

The AlGaN barrier layer shown in FIG. 5 is a material in which In composition is 0 in AlxGayIn1-x-yN satisfying the above formulas. Similarly, the GaN well layer is a material in which In composition and Al composition are 0 in Alx′Gay′In1-x′-y′N satisfying the above formulas.

When such a quantum well structure is formed, as shown in FIG. 6, Eu³⁺ ions can be sufficiently moved to the well layer to increase the carrier density around Eu. As a result, it is possible to emit red or green light with higher emission intensity.

Also, Mg, doped as an impurity, is introduced to a level shallower than the native defects of GaN, moves in a band gap narrower than the band gap (εg(well)) in the GaN:Eu layer and emits blue light. Therefore, even with a low injection current, blue light can be emitted with high emission intensity at the same time as the red light emission. As described above, when Si is doped in addition to Mg, the emission intensity of blue light can be further increased, which is preferable. This quantum well layer may be a single layer.

(3) Manufacture of a Color Tunable Light Emission Diode

Hereafter, the procedure for manufacturing a color tunable light emission diode according to the present embodiment will be described with reference to the manufacture of the color tunable light emission diode shown in FIG. 5 as a specific example.

First, an LT-GaN layer was formed on a sapphire substrate using an organometallic vapor phase epitaxy (OMVPE method), and then an ud-GaN layer having a thickness of about 1 μm was formed on the LT-GaN layer.

It is possible to prevent the occurrence of cracks due to a difference in lattice constant between sapphire and GaN and suppress the influence of dislocation due to the sapphire substrate by providing such an LT-GaN layer and a ud-GaN layer.

Next, an n-GaN layer having a thickness of about 1.5 μm was formed on the ud-GaN layer using the OMVPE method, similarly.

Next, using the OMVPE method, similarly, a step of forming an AlGaN layer having a thickness of about 5 nm (Al concentration: 20%), an ud-GaN layer having a thickness of about 1 nm, a GaN:Eu layer having a thickness of about 1 nm and an ud-GaN layer having a thickness of about 1 nm in this order is repeated thirteen times on the n-GaN layer. Thereafter, an AlGaN layer having a thickness of about 5 nm is formed, thereby forming a 13-period AlGaN/GaN:Eu multiple quantum well (MQW) structure (growth temperature: 960° C.). When forming the GaN:Eu layer, Mg and Si as impurities were simultaneously doped together with Eu.

Next, a p+-GaN/p-GaN layer was formed on the AlGaN layer using the OMVPE method, similarly. Thus, a pn junction diode structure can be formed with the previously formed n-GaN layer.

Each of the above-described steps was performed in a series of steps while maintaining the pressure in the reaction vessel at 100 kPa and without taking out the sample from the reaction vessel on the way. In each of the above steps, trimethylgallium (TMGa) was used as the Ga source, ammonia (NH3) was used as the nitrogen source, and trimethylaluminum (TMA) was used as the Al source. As the Eu source, EuCppm2 having a high vapor pressure was used from among organic Eu compounds such as EuCppm2 and Eu(DPM)3 (supply temperature: 125° C.). Further, Cp2Mg was used as the Mg source, and monomethylsilane (MMSi) was used as the Si source.

The Eu concentration of each active layer of the fabricated device was measured by secondary ion mass spectrometry, and it was estimated to be 5.6×1019 cm−3. The Mg concentration was estimated to be 1×1019 cm−3, and the Si concentration was estimated to be 3×1018 cm−3.

2. Micro LED Display

As described above, the device according to the present embodiment can use one Eu-doped GaN LED as a color tunable light emission diode. Therefore, one pixel can be constituted by one LED chip, and the size of the pixel can be miniaturized as small as possible. Therefore, when a display unit is formed by integrating the pixels having such a light emission diode, ultra-miniaturization of the micro LED display is possible. And since more pixels can be arranged in the same area, the screen can be made higher definition.

Note that, in place of the above-described three-color tunable light emission diode, a display can be constituted using a pixel in which

a GaN LED for emitting red and green light to which Mg is not doped and a Mg-doped GaN LED for emitting blue light are arranged. However, in this case, since two LEDs are arranged to form one pixel, although the pixel size can be made smaller than in the conventional case, extent of the size miniaturization is not to the extent in the above-described embodiment.

What is claimed is:

1. A color tunable light emission diode in which the color tone of the emission color changes by controlling the injection current, comprising:
an active layer sandwiched between a p-type layer and an n-type layer on a substrate; and
the active layer is formed by doping Eu and Mg to an AlGaInN-based material which is GaN, InN, AlN or a mixed crystal of any two or more of them.

2. The color tunable light emission diode according to claim 1, wherein
the active layer has a quantum well structure in which barrier layers made of AlGaInN-based material and well layers made of AlGaInN-based material are alternately stacked;
when the AlGaInN-based material of the barrier layer is a material represented by AlxGayIn1-x-yN, and the AlGaInN-based material of the well layer is a material represented by Alx′Gay′In1-x′-y′N, x, x′, y and y′ are set so that the electron affinity κ(barrier) and band gap εg(barrier) of the AlxGayIn1-x-yN, and the electron affinity κ(well) and band gap εg(well) of the Alx′Gay′In1-x′-y′N satisfy the following formulas:
κ_{(barrier)}<κ_{(well)}
κ_{(barrier)}+ε_{g(barrier)}>κ_{(well)}+ε_{g(well)}

3. The color tunable light emission diode according to claim 1, wherein the barrier layer is an AlGaN layer, and the well layer is a GaN layer.

4. The color tunable light emission diode according to claim 1, wherein the amount of Eu doped to each of the well layers is 1×10¹⁷ to 5×10²¹ cm⁻³.

5. The color tunable light emission diode according to claim 1, wherein the amount of Mg doped to each of the well layers is 1×10¹⁸ to 1×10²⁰ cm⁻³.

6. The color tunable light emission diode according claim 1, wherein Si is further doped to each of the well layers.

7. The color tunable light emission diode according to claim 6, wherein the amount of Si doped to each of the well layers is 1×10¹⁷ to 5×10²¹ cm⁻³.

8. The color tunable light emission diode according to claim 1, wherein the thickness of the barrier layer is 0.5 to 50 nm per layer, and the thickness of the well layer is 0.1 to 20 nm per layer.

9. The color tunable light emission diode according to claim 1, wherein an ud-GaN layer is formed as a buffer layer between the barrier layer and the well layer.

10. The color tunable light emission diode according claim 1, wherein the thickness of the buffer layer is 0.1 to 20 nm per layer.

11. The color tunable light emission diode according to claim 2, wherein the barrier layer is an AlGaN layer, and the well layer is a GaN layer.

12. The color tunable light emission diode according to claim 11, wherein the amount of Eu doped to each of the well layers is 1×10¹⁷ to 5×10²¹ cm⁻³.

13. The color tunable light emission diode according to claim 12, wherein the amount of Mg doped to each of the well layers is 1×10¹⁸ to 1×10²⁰ cm⁻³.

14. The color tunable light emission diode according claim 13, wherein Si is further doped to each of the well layers.

15. The color tunable light emission diode according to claim 14, wherein the amount of Si doped to each of the well layers is 1×10¹⁷ to 5×10²¹ cm⁻³.

16. The color tunable light emission diode according to claim 15, wherein the thickness of the barrier layer is 0.5 to 50 nm per layer, and the thickness of the well layer is 0.1 to 20 nm per layer.

17. The color tunable light emission diode according to claim 16, wherein a ud-GaN layer is formed as a buffer layer between the barrier layer and the well layer.

18. The color tunable light emission diode according to claim 17, wherein the thickness of the buffer layer is 0.1 to 20 nm per layer.

19. A micro LED display, wherein its display unit is formed by integrating image pixels having the color tunable light emission diode according to claim 1.

20. A micro LED display comprising:
a display unit formed by integrating image pixels each of which is formed by arranging a light emission diode in which Eu is doped to an AlGaInN-based material that is GaN, InN, AN or a mixed crystal of any two or more of them and a light emission diode in which Mg is doped to an AlGaInN-based material that is GaN, InN, AlN or a mixed crystal of any two or more of them, on a same pixel substrate.
